(19) United States
(12) Patent Application Publication
(10) Pub. No.: US 2012/0098530 A1
(43) Pub. Date: Apr. 26, 2012

(54) PIEZOELECTRIC/MAGNETOSTRICTIVE COMPOSITE MAGNETIC SENSOR

(75) Inventors: Chihiro Saito, Tokyo (JP); Motoichi Nakamura, Tokyo (JP); Teiko Okazaki, Aomori (JP); Yasubumi Furuya, Aomori (JP)

(73) Assignee: NAMIKI SEIMITSU HOUSEKI KABUSHIKI KAISHA, Tokyo (JP)

(21) Appl. No.: 13/258,269

(22) PCT Filed: Mar. 26, 2010
(86) PCT No.: PCT/JP2010/055371

§ 371 Date: Nov. 3, 2011

(30) Foreign Application Priority Data
Mar. 26, 2009 (JP) 2009-076931

(51) Int. Cl. G01R 33/18

(52) U.S. Cl. 324/209

(57) ABSTRACT

[Object] Disclosed is a highly sensitive piezoelectric/magnetostrictive composite magnetic sensor which has a simple structure and thus can be downsized easily.

[Solving Means] Film(s) of magnetostrictive material, which is composed of an Fe alloy containing Pd, Ga, Co and the like, is(are) formed and integrated on at least one surface of a piezoelectric ceramic substrate by a sputtering method. When the magnetostrictive material is deformed by an external magnetic field, a stress is applied to the piezoelectric material that is integrated with the magnetostrictive material. The voltage generated by the change in the polarization within the piezoelectric material, said change being caused by the stress, is sensed as an output of the magnetic sensor.

### TECHNICAL FIELD

The present invention relates to a magnetic sensor for use in detecting a small variation of a magnetic field, and more particularly, to a piezoelectric/magnetostrictive composite magnetic sensor using a combination of a piezoelectric effect and a magnetostriction phenomenon.

### BACKGROUND ART

Hall sensors that utilize Hall effect have been widely used as typical magnetic sensors heretofore. In addition, various types of magnetic sensors are selected and used depending on the intended use.

Among the magnetic sensors, as an exemplary magnetic sensor including a magnetostrictive element and a piezoelectric element as constituent elements, Patent Document 1, for example, discloses a magnetic sensor including a magnetostrictive element and a piezoelectric element that are bonded together.

The magnetic sensor disclosed in Patent Document 1 has a basic principle of detecting a change in shape of a magnetostrictive element due to a change in external magnetic field as a voltage generated in a piezoelectric element integrated with the magnetostrictive element.

In other words, the magnetic sensor is configured to detect a voltage generated due to displacement of the piezoelectric element upon receiving a stress during a change in magnetic strain of the magnetostrictive element. Whether the magnetic sensitivity of the magnetic sensor is good or not depends on the voltage generated in the piezoelectric element.

On the other hand, Patent Document 2 discloses a magnetic sensor having a sensor structure in which a laminate of magnetostrictive thin film deposited on a piezoelectric body using films formation technique, such as sputtering, is disposed on a support substrate.

The magnetic sensor disclosed in Patent Document 2 has a basic principle of calculating the amount of external magnetic field based on the amount of change in resonance frequency of a sensor structure that changes with a change in the external magnetic filed in the state where the sensor structure is mechanically vibrating in an integrated manner.

In this method, the magnetic sensitivity does not depend on the voltage generated in the piezoelectric element. Therefore, both downsizing and higher sensitivity can be easily achieved, as compared with the magnetic sensor employing the method in the example of Patent Document 1.

### RELATED ART DOCUMENT

### Patent Document

Patent Document 1: JP-A-2000-088937

Patent Document 2: WO2004/070408

### DISCLOSURE OF INVENTION

### Problems to be Solved by the Invention

In the case of the magnetic sensor of the type in which the magnetostrictive element and the piezoelectric element are bonded together, the magnitude of the generated voltage involving the magnetic sensitivity is determined by, for example, piezoelectric or magnetostrictive characteristics, size, rigidity of each element. This makes it difficult to meet the requirements for downsizing and higher sensitivity at the same time.

It can be said that it is particularly difficult to downsize the sensor to such a level that can be used in a magnetic encoder for micromotors or can be incorporated in various microactuators to be used for position detection control.

As for the characteristics of the magnetostrictive element to be used, the amount of strain does not increase linearly with respect to the strength of the magnetic field, though the amount of strain increases as the strength of the magnetic field affecting each element increases. Accordingly, when the magnetostrictive element is used for the magnetic sensor, a superior magnetic field area varies depending on the type of the magnetostrictive element to be used.

As the material of the magnetostrictive element, a so-called giant magnetostrictive material with a large strain may be suitably used. However, the giant magnetostrictive material typically includes a rare earth element, which poses a problem of increase in cost.

As for bonding of the magnetostrictive element and the piezoelectric element, when bulk materials of these elements are bonded together with an adhesive, the adhesive functions as a buffer material, which may deteriorate a magnetoelectric conversion efficiency. Further, this may cause peeling from an adhesive joint depending on use conditions.

Meanwhile, in the case of the magnetic sensor of the type that calculates the amount of external magnetic field based on the amount of shift in resonance frequency, it may be necessary to configure and dispose a circuit for detecting a mechanical resonance frequency. Accordingly, it is difficult to achieve downsizing to such a level that can be incorporated into various microactuators, and costs tend to increase.

### Solutions to the Problems

In order to solve the above-mentioned problems, an invention set forth in claim 1 provides a piezoelectric/magnetostrictive composite magnetic sensor including magnetostrictive film(s) composed of an Fe alloy, the magnetostrictive film(s) being deposited on at least one surface of a piezoelectric substrate.

An invention set forth in claim 2 provides a piezoelectric/magnetostrictive composite magnetic sensor including magnetostrictive film(s) composed of an Fe alloy containing Pd, the magnetostrictive film(s) being deposited on at least one surface of a piezoelectric substrate.

An invention set forth in claim 3 provides a piezoelectric/magnetostrictive composite magnetic sensor including magnetostrictive film(s) composed of an Fe alloy containing Ga, the magnetostrictive film(s) being deposited on at least one surface of a piezoelectric substrate.

An invention set forth in claim 4 provides a piezoelectric/magnetostrictive composite magnetic sensor including magnetostrictive film(s) composed of an Fe alloy containing Co, the magnetostrictive film(s) being deposited on at least one surface of a piezoelectric substrate.

An invention set forth in claim 5 provides a piezoelectric/magnetostrictive composite magnetic sensor including laminated film(s) of magnetostrictive film(s) composed of two or more types of Fe alloys having different compositions, the laminated film(s) being deposited on at least one surface of a piezoelectric substrate.

An invention set forth in claim 6 provides a piezoelectric/magnetostrictive composite magnetic sensor including laminated film(s) of magnetostrictive film(s) composed of an Fe alloy containing Pd and magnetostrictive film(s) composed of an Fe alloy containing Co, the laminated film(s) being deposited on at least one surface of a piezoelectric substrate.

An invention set forth in claim 7 provides a piezoelectric/magnetostrictive composite magnetic sensor including laminated film(s) of magnetostrictive film(s) composed of an Fe alloy containing Ga and magnetostrictive film(s) composed of an Fe alloy containing Co, the laminated film(s) being deposited on at least one surface of a piezoelectric substrate.

An invention set forth in claims 8 to 15 may provide the piezoelectric/magnetostrictive composite magnetic sensor set forth in any one of claims 1 to 7, in which magnetostrictive films are deposited on both surfaces of the piezoelectric substrate.

### Effects of the Invention

According to the present invention, it is possible to achieve a magnetic sensor that has a high sensitivity and can be downsized with a simple structure and at low cost by forming magnetostrictive films on a piezoelectric substrate using a magnetostrictive material of an Fe alloy.

For example, compared with a Hall sensor, the magnetic sensor has a several-fold resolution and a high frequency responsiveness of several MHz. Furthermore, input power is not needed for detecting an AC magnetic field, so that each magnetic sensor element has no power consumption.

In particular, when an Fe alloy containing Pd is used as a magnetostrictive material, a magnetic sensor having a higher sensitivity can be obtained, because the Fe alloy containing Pd has a large amount of strain with respect to a change in magnetic field among other Fe alloys.

In particular, when an Fe alloy containing Ga is used as a magnetostrictive material, a magnetic sensor having a higher sensitivity can be obtained at lower cost, because Ga is more easily obtained compared to, for example, Pd and a sufficient amount of magnetic strain can be obtained even at a composition ratio between Ga and Fe of about 10 to 20%.

In particular, when an Fe alloy containing Co is used as a magnetostrictive material, a stress generated by a magnetic strain can be effectively given to a piezoelectric substrate, because the Fe alloy containing Co has a higher Young's modulus among other Fe alloys.

Further, according to the present invention, it is possible to obtain a magnetic sensor having good characteristics of magnetostrictive materials of each composition by depositing laminate of magnetostrictive films composed of two or more types of Fe alloys having different compositions on a piezoelectric substrate.

In particular, when laminated films of magnetostrictive films composed of an Fe alloy containing Pd and magnetostrictive films composed of an Fe alloy containing Co is deposited, a magnetic sensor having a high sensitivity and a linear characteristic in a wide range can be obtained.

In particular, when laminated films of magnetostrictive films composed of an Fe alloy containing Ga and magnetostrictive films composed of an Fe alloy containing Co is deposited, a magnetic sensor having a linear characteristic in a wide range can be obtained at relatively low cost.

Furthermore, according to the present invention, when magnetostrictive films are deposited on one surface of a piezoelectric substrate, a strain of the magnetic sensor during magnetic detection occurs in a bending direction. Meanwhile, when magnetostrictive films are deposited on both surfaces of the piezoelectric substrate, the strain occurs due to expansion and contraction.

As a result of the strain of the magnetic sensor due to expansion and contraction, the magnetic sensor can be held at both ends. Consequently, fixation is facilitated, and reduction in possibility of having an adverse effect of disturbance and improvement in durability are expected.

### BEST MODE FOR CARRYING OUT THE INVENTION

The best mode of the present invention is a structure in which a magnetostrictive material composed of an Fe alloy containing any one of Pd, Ga, and Co is deposited on a substrate composed of a piezoelectric material.

In particular, when two or more types of combinations of Fe alloys containing about 10 to 50% of any one of Pd, Ga, and Co are laminated and deposed on both surfaces of a piezoelectric substrate, a piezoelectric/magnetostrictive composite magnetic sensor having a higher sensitivity and a linear characteristic in a wide range can be obtained.

As for the Fe alloy containing Pd, an alloy containing 27 to 32 at % Pd is preferably used. As illustrated in the phase diagram of FIG. 1, an Fe alloy containing 27 to 32 at % Pd has a face-centered tetragonal structure (FCT) that causes magnetic field-induced twinned martensitic phase transformation, with the result that a large magnetic strain occurs. Therefore, a magnetic sensor having a higher sensitivity can be achieved.

Hereinafter, specific embodiments of the present invention will be described with reference to the drawings.

### First Embodiment

### [Production of Piezoelectric/Magnetostrictive Composite Magnetic Sensor]

FIG. 2 is an illustration of a piezoelectric/magnetostrictive composite magnetic sensor 1 according to this embodiment. The piezoelectric/magnetostrictive composite magnetic sensor 1 has a structure in which magnetostrictive films M are deposited on both surfaces of a piezoelectric ceramic substrate P.

Specifically, the magnetostrictive films M having an area of 10×18 mm are deposited with a thickness of 2 μm on both surfaces of each of three piezoelectric ceramic substrates P (relative permittivity ε₃₃/ε₀=5500, piezoelectric constant d₃₁=−330×10⁻¹² C/N, mechanical quality factor Q=30) of 10×20×0.26 mm.

On the three piezoelectric ceramic substrates, Fe magnetostrictive materials having the following compositions are deposited.

### (1) Fe-30 at Pd (2) Fe-20 at % Ga (3) Fe-50 at % Co

An RF magnetron sputtering machine was used to form the magnetostrictive films at an RF power density of 2.2 W/cm² and a gas pressure of 0.2 to 1 Pa. In order to impart magnetic anisotropy to the magnetostrictive films, a magnetic field of about 100 Oe was applied to carry out deposition.

### [Measurement of Piezoelectric/Magnetostrictive Composite Magnetic Sensor]

With the structure illustrated in the measurement block diagram of FIG. 3, an output voltage of each sensor having different compositions of magnetostrictive aterials was measured. As a magnetic field H, an AC magnetic field H=170 Oe of a sine wave and a frequency f=1 Hz were applied using an air core coil. A charge amplifier has a gain of 1.26 mV/pC.

FIG. 4 is a graph illustrating output voltages with respect to magnetic fields of three types of magnetic sensors for comparison. From this result, it was confirmed that particularly a magnetic sensor using (1) Fe-30 at % Pd film has a higher output voltage compared to the case where other Fe magnetostrictive materials are used. In particular, it was confirmed that the magnetic sensor has a steep slope at a magnetic field H=80 Oe or lower and has a high magnetic sensitivity.

### Second Embodiment

Next, in a second embodiment, an effect of changing the film thickness of the magnetic sensor using the Fe-30 at % Pd film was examined.

Fe-30 at % Pd film having film thicknesses of t=2 μm and t=10 μm were prepared as a sample.

Conditions for production and measurement of a magnetic sensor are the same as those of the first embodiment, except the film thickness t=10 μm.

FIG. 5 is a graph illustrating output voltages in each magnetic field of the magnetic sensor using Fe-30 at % Pd film having film thicknesses of t=2 μm and t=10 μm according to this embodiment. From this result, it was confirmed that in the magnetic sensor having a thickness t=10 μm, an output voltage about ten times greater than that of the magnetic sensor having a thickness t=2 μm was obtained.

### Third Embodiment

FIG. 6 is an illustration of a piezoelectric/magnetostrictive composite magnetic sensor 2 according to this embodiment. The piezoelectric/magnetostrictive composite magnetic sensor 2 has a structure in which two types of magnetostrictive films Mp and Mc having different compositions are deposited on both surfaces of the piezoelectric ceramic substrate P.

Specifically, the Fe-30 at % Pd magnetostrictive films Mp each having an area of 10×18 mm were first deposited with a thickness of 2 μm on both surfaces of the piezoelectric ceramic substrate P (relative permittivity ε₃₃/ε₀=5500, piezoelectric constant d₃₁=−330×10⁻¹² C/N, mechanical quality factor Q=30) of 10×20×0.26 mm. Further, the Fe-50 at % Co magnetostrictive films Mc were deposited thereon with a thickness of 2 μm.

Conditions for production and measurement of a magnetic sensor are the same as those of the first embodiment, except that the magnetostrictive films have a laminated structure.

FIG. 7 is a graph illustrating output voltages of the magnetic sensor with respect to the magnitude of each magnetic field. The graph illustrates outputs of the sample obtained by depositing laminated films of Fe-30 at % Pd and Fe-50 at % Co on the piezoelectric ceramic substrate P according to this embodiment, and output results in the case where Fe-30 at % Pd was deposited into a single layer and output results in the case where Fe-50 at % Co was deposited into a single layer.

As seen from FIG. 7, the magnetic sensor using the Fe-30 at % Pd film has a steep slope and a high sensitivity at H=80 Oe or lower, and particularly has high performance at a weak magnetic field.

Further, the magnetic sensor using the Fe-50 at % Co film has about the same sensitivity as that of an Ni film of a conventional material at H=100 Oe or lower, but has a higher sensitivity at H=100 Oe or higher. Accordingly, the magnetic sensor has superiority in the magnetic field H=100 Oe or higher.

As a result of combining the Fe-30 at % Pd film having superiority in a magnetic field H=80 Oe or lower with the Fe-50 at % Co film having superiority in a magnetic field H=100 Oe or higher, a magnetic sensor having good properties of the both films and a linear characteristic was obtained as shown in FIG. 7.

### Fourth Embodiment

Next, in a fourth embodiment, a sample was prepared by depositing laminated films of an Fe-20 at % Ga film and an Fe-50 at % Co film on a piezoelectric ceramic substrate.

In comparison with the third embodiment, conditions for production and measurement of a magnetic sensor are the same as those of the third embodiment, except that the Fe-30 at % Pd film was replaced with an Fe-20 at % Ga film with a thickness of 2 μm.

FIG. 8 is a graph illustrating output voltages of the magnetic sensor with respect to the magnitude of each magnetic field. The graph illustrates outputs of the sample obtained by depositing laminated films of Fe-20 at % Ga and Fe-50 at % Co on the piezoelectric ceramic substrate P according to this embodiment, and output results in the case where Fe-20 at % Ga was depositing into a single layer and output results in the case where Fe-50 at % Co was deposited into a single layer.

The magnetic sensor using single-layer films of Fe-20 at % Ga has a higher sensitivity at a magnetic field H=50 Oe or lower as compared to the Ni film of the conventional material, for example, although they are less than those of the Fe-30 at % Pd film. This is effective in detection of a weak magnetic field.

The magnetic sensor using the Fe-50 at % Co film has substantially the same sensitivity as the Ni film of the conventional material at H=100 Oe or lower, but has a higher sensitivity at H=100 Oe or higher. Accordingly, the magnetic sensor has superiority in the magnetic field H=100 Oe or higher.

As a result of combining an Fe-20 at % Ga film having superiority in a magnetic field H=50 Oe or lower with an Fe-50 at % Co film having superiority in a magnetic field H=100 Oe or higher, a magnetic sensor having good properties of both the films and a linear characteristic was obtained as shown in FIG. 8.

### Fifth Embodiment

Next, in a fifth embodiment, the linearity of a magnetic sensor using an Fe-30 at % Pd thin film was examined. A sample was prepared by depositing an Fe-30 at % Pd having a film thickness t=10 μm on the piezoelectric ceramic substrate used in the first embodiment. The size of the sample was 1×1 mm.

An output voltage was measured when an AC magnetic field H=10 Oe and a frequency f=1 Hz were applied and a DC magnetic field Hdc of 40 to 60 Oe was applied. The charge amplifier has a gain of 500 mV/pC.

FIG. 9 is a graph illustrating output voltages with respect to the applied magnetic fields according to this embodiment. From this result, it was confirmed that the magnetic sensor has a good linearity of 1% or lower.

### Sixth Embodiment

Next, in a sixth embodiment, temperature characteristics of a magnetic sensor using an Fe-30 at % Pd thin film were examined. A sample similar to that of the fifth embodiment was used.

As measurement conditions at this time, an AC magnetic field H=10 Oe and a frequency f=1 Hz were applied and a DC magnetic field Hdc of 100 Oe was applied.

FIG. 10 is a graph illustrating output voltages in a temperature range of −40 to +120° C. according to this embodiment. From this result, it was confirmed that the output voltage has a temperature coefficient of 0.8 mV/° C. and has a linear characteristic.

The embodiments have been described above, but the present invention is not limited to the above embodiments and various modified examples can be adopted within the scope of the present invention. For example, the type, size, and shape of the piezoelectric element, the films formation range of the magnetostrictive material, the deposited film thickness, combinations of laminated films, the number of laminates can be appropriately selected depending on the intended use.

### INDUSTRIAL APPLICABILITY

A piezoelectric/magnetostrictive composite magnetic sensor of the present invention has a simple structure and good mechanical workability and can be processed in various sizes to be used. Moreover, the piezoelectric/magnetostrictive composite magnetic sensor is capable of detecting magnetic fields in a wider range. Therefore, the piezoelectric/magnetostrictive composite magnetic sensor can be employed in various devices requiring magnetic detection, such as a magnetic encoder for micromotors, and a torque sensor for vehicles.

### BRIEF DESCRIPTION OF THE DRAWINGS

FIG. 1 is a phase diagram of an Fe-Pd alloy.

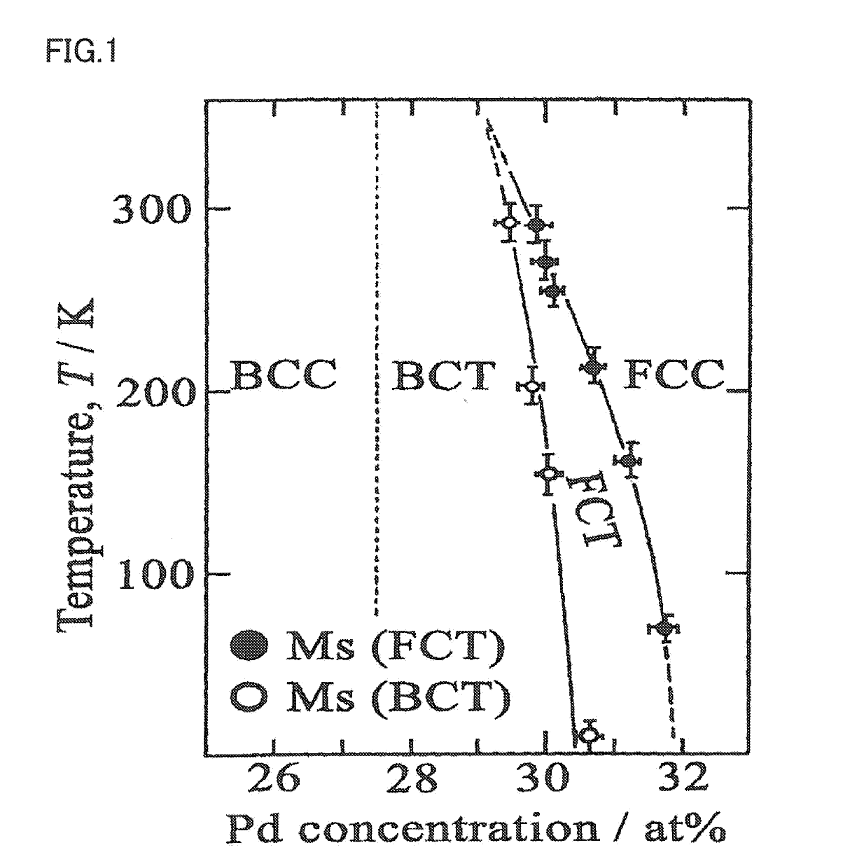

FIG. 2 is a structural diagram of a piezoelectric/magnetostrictive composite magnetic sensor according to an embodiment of the present invention.

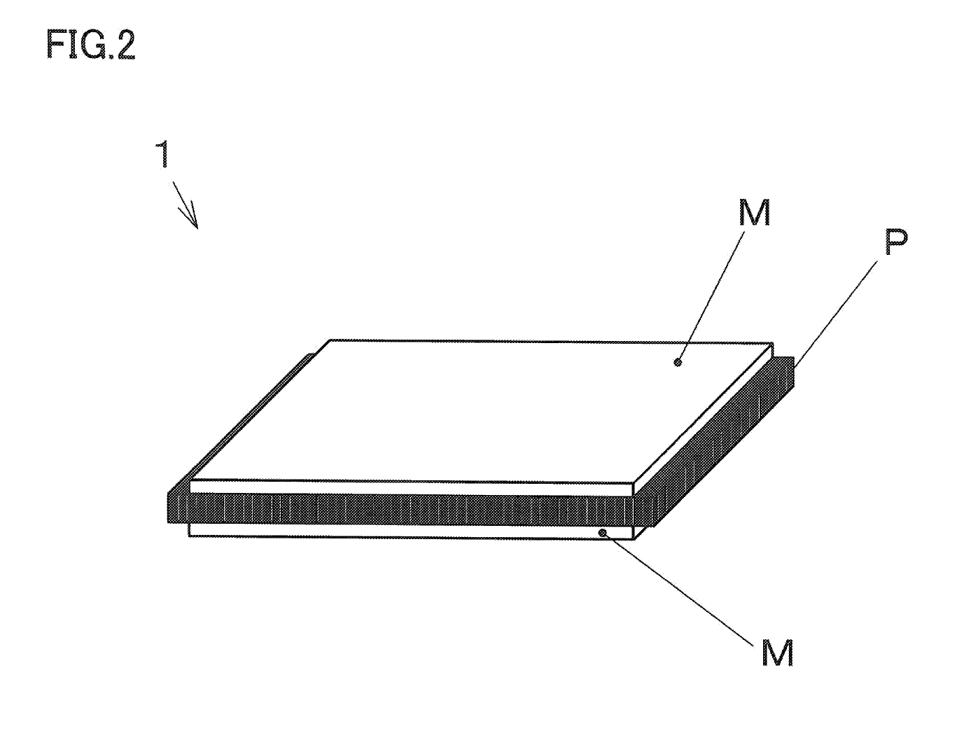

FIG. 3 is a measurement block diagram of an output voltage of a magnetic sensor according to an embodiment of the present invention.

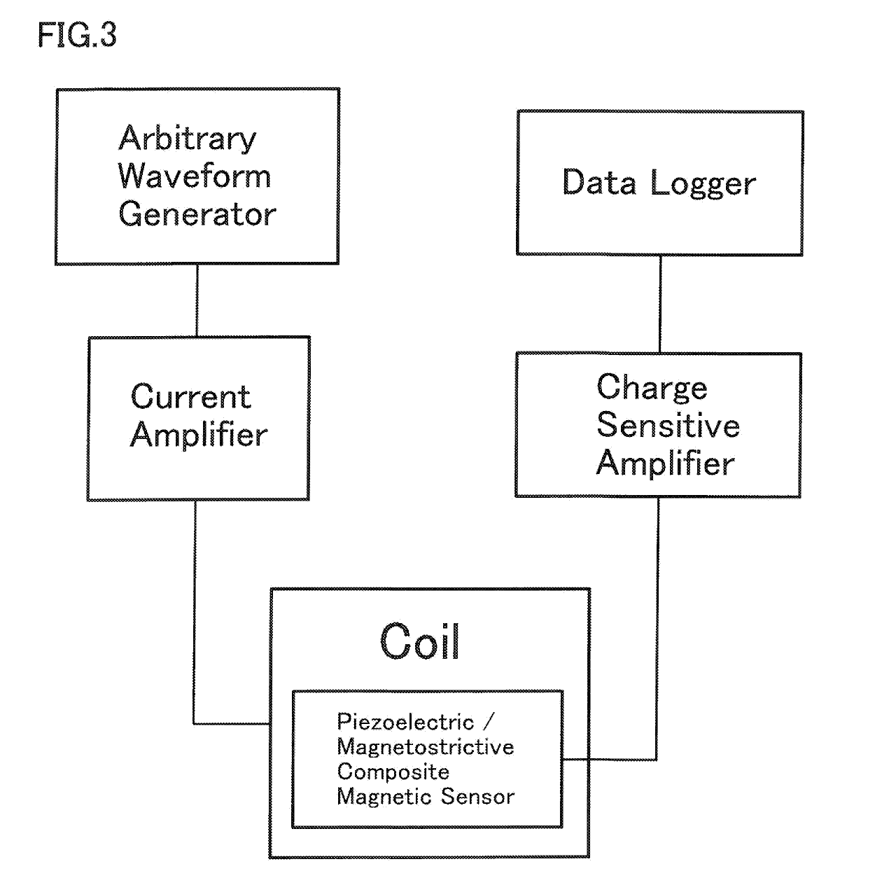

FIG. 4 is an output characteristics of a magnetic sensor according to an embodiment of the present invention.

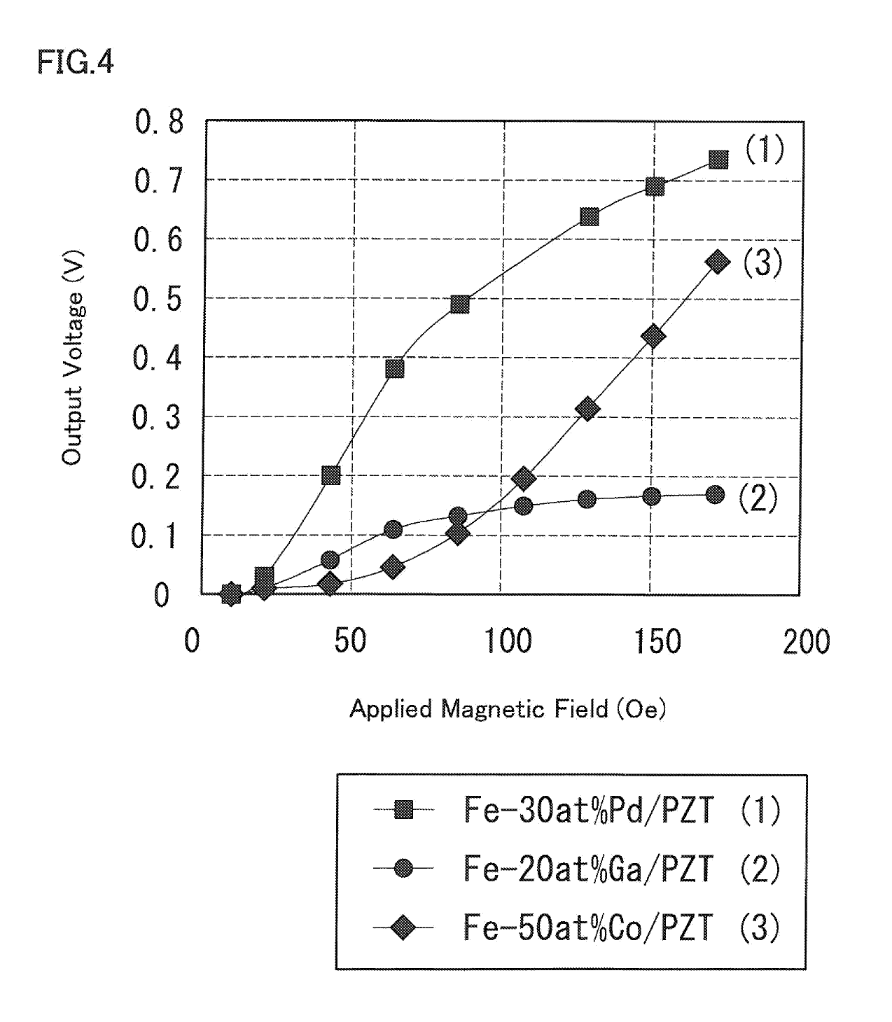

FIG. 5 is an output characteristics of a magnetic sensor according to an embodiment of the present invention.

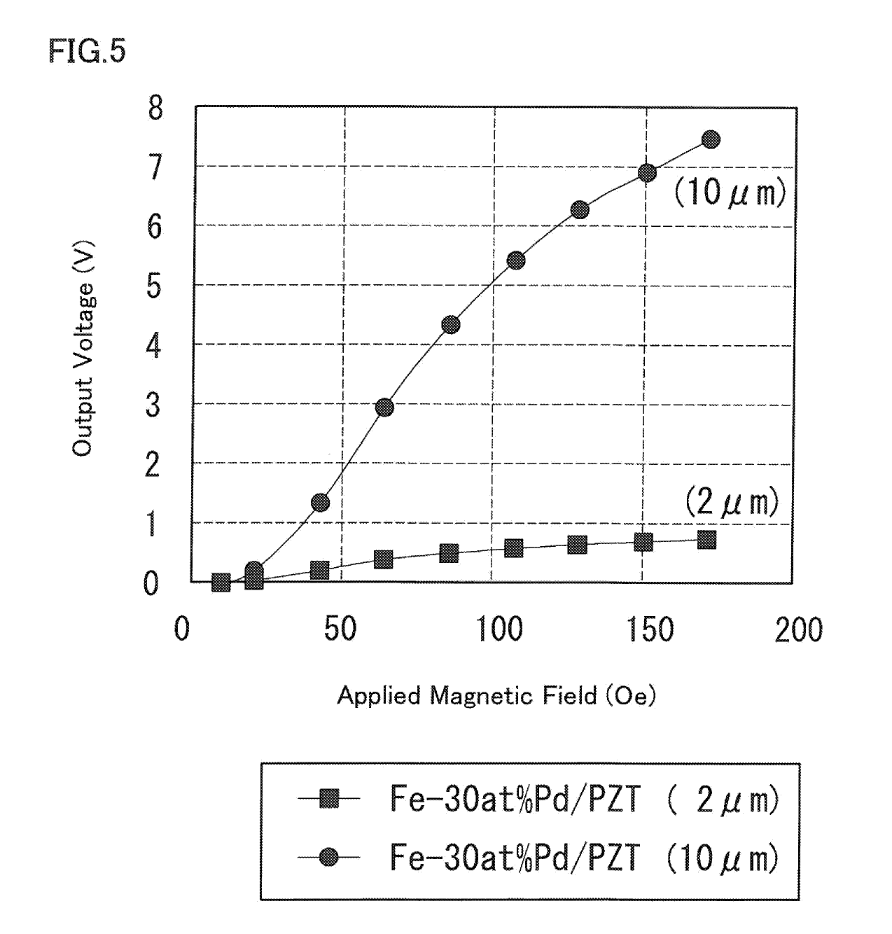

FIG. 6 is a structural diagram of a piezoelectric/magnetostrictive composite magnetic sensor according to an embodiment of the present invention.

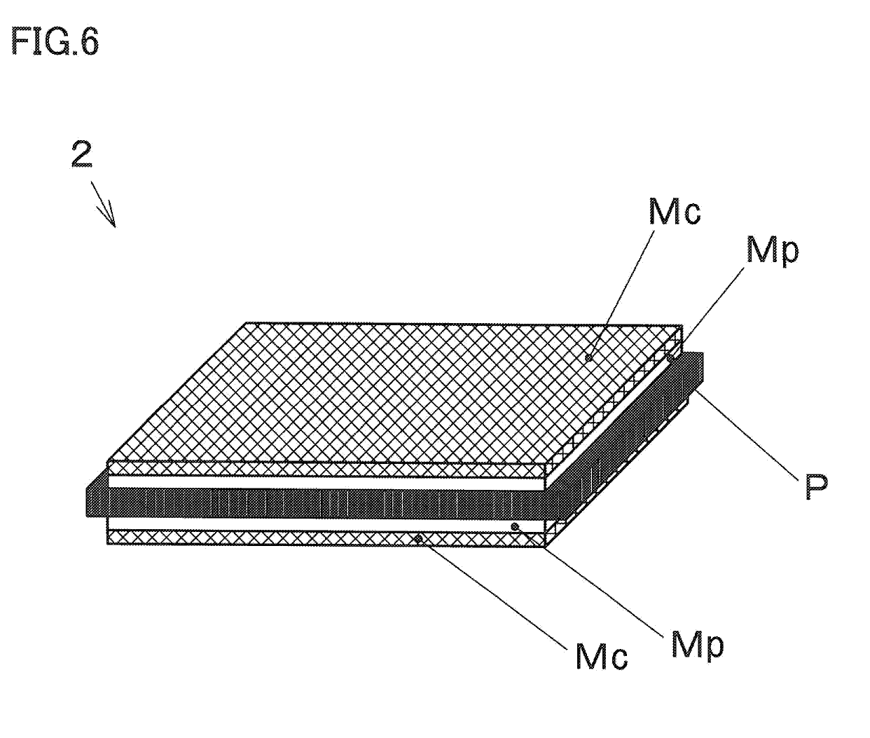

FIG. 7 is an output characteristics of a magnetic sensor according to an embodiment of the present invention.

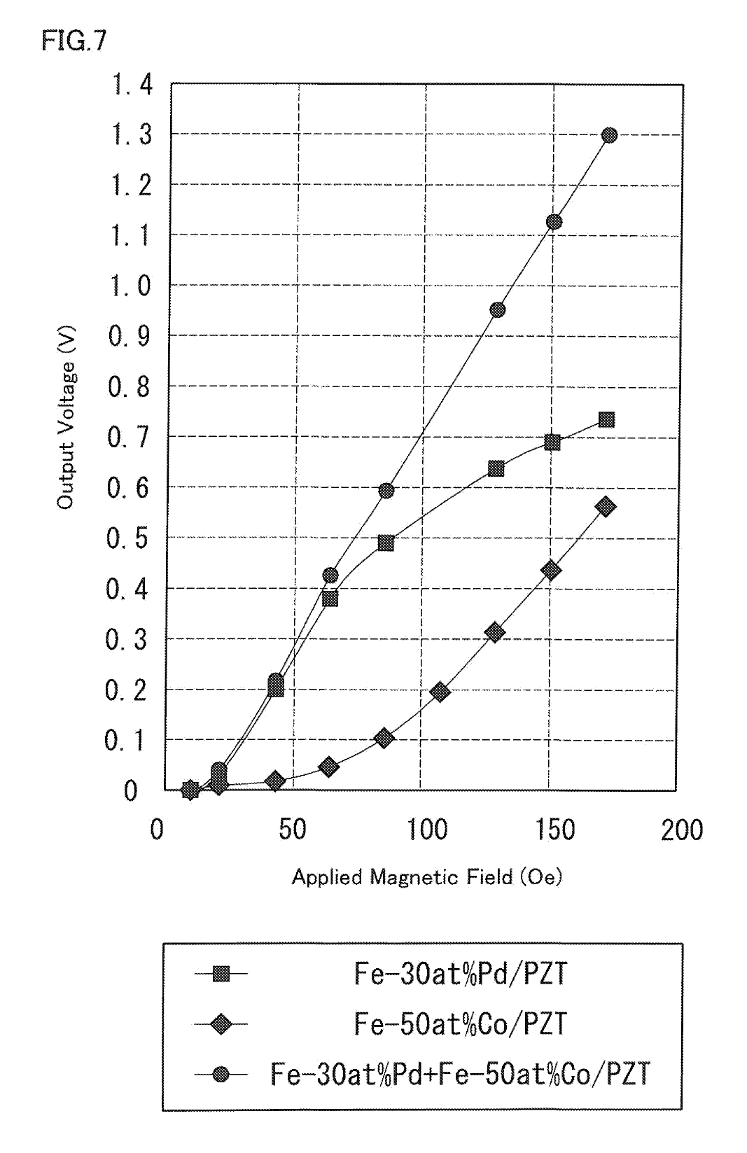

FIG. 8 is an output characteristics of a magnetic sensor according to an embodiment of the present invention.

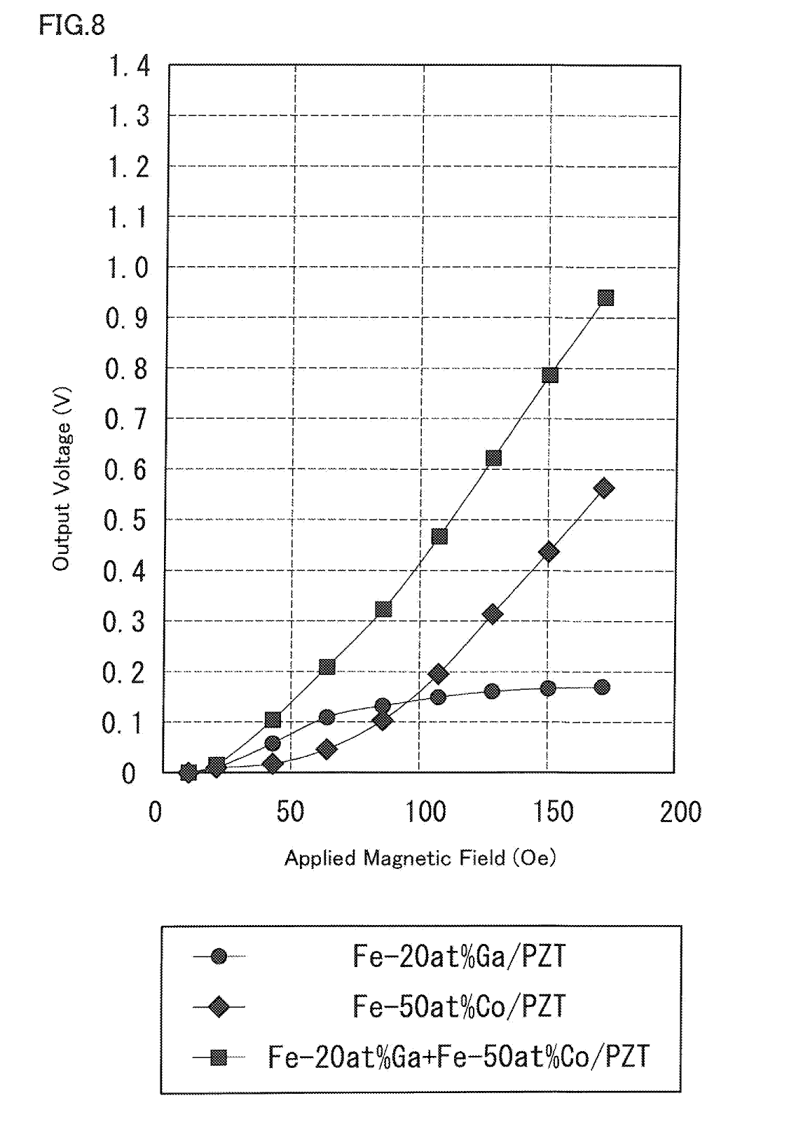

FIG. 9 is an output characteristics of a magnetic sensor according to an embodiment of the present invention.

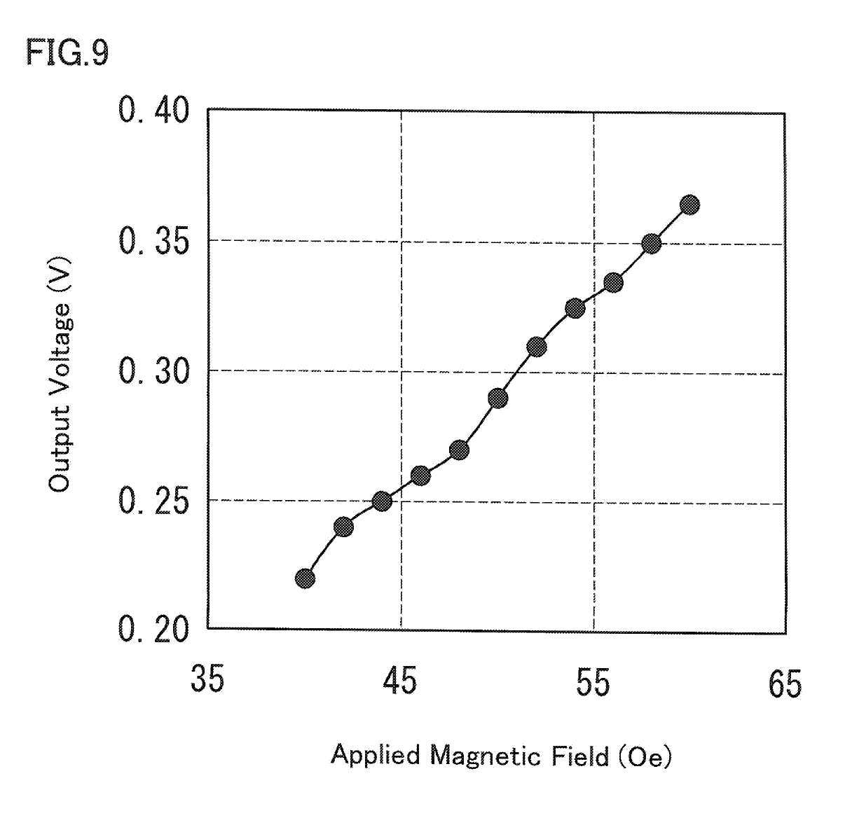

FIG. 10 is an output characteristics of a magnetic sensor according to an embodiment of the present invention.

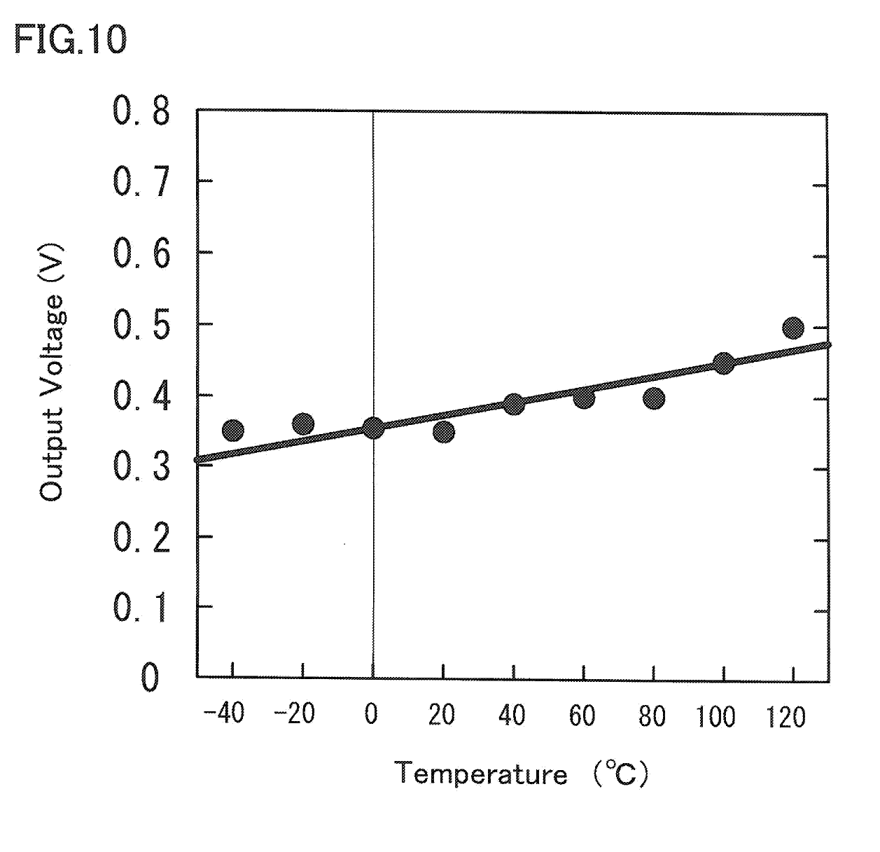

### DESCRIPTION OF REFERENCE SIGNS

1 PIEZOELECTRIC/MAGNETOSTRICTIVE COMPOSITE MAGNETIC SENSOR (MAGNETOSTRICTIVE FILM SINGLE LAYER)
2 PIEZOELECTRIC/MAGNETOSTRICTIVE COMPOSITE MAGNETIC SENSOR (MAGNETOSTRICTIVE FILM LAMINATE)
P PIEZOELECTRIC CERAMIC SUBSTRATE
M MAGNETOSTRICTIVE FILM
Mp MAGNETOSTRICTIVE FILM (Fe-30 at % Pd)
Mc MAGNETOSTRICTIVE FILM (Fe-50 at % Co)

1. A piezoelectric/magnetostrictive composite magnetic sensor, comprising magnetostrictive film(s) composed of an Fe alloy, the magnetostrictive film(s) being deposited on at least one surface of a piezoelectric substrate.

2. A piezoelectric/magnetostrictive composite magnetic sensor, comprising magnetostrictive film(s) composed of an Fe alloy containing Pd, the magnetostrictive film(s) being deposited on at least one surface of a piezoelectric substrate.

3. A piezoelectric/magnetostrictive composite magnetic sensor, comprising magnetostrictive film(s) composed of an Fe alloy containing Ga, the magnetostrictive film(s) being deposited on at least one surface of a piezoelectric substrate.

4. A piezoelectric/magnetostrictive composite magnetic sensor, comprising magnetostrictive film(s) composed of an Fe alloy containing Co, the magnetostrictive film(s) being deposited on at least one surface of a piezoelectric substrate.

5. A piezoelectric/magnetostrictive composite magnetic sensor, comprising laminated film(s) of magnetostrictive film(s) composed of two or more types of Fe alloys having different compositions, the laminated film(s) being deposited on at least one surface of a piezoelectric substrate.

6. A piezoelectric/magnetostrictive composite magnetic sensor, comprising laminated film(s) of magnetostrictive film(s) composed of an Fe alloy containing Pd and magnetostrictive film(s) composed of an Fe alloy containing Co, the laminated film(s) being deposited on at least one surface of a piezoelectric substrate.

7. A piezoelectric/magnetostrictive composite magnetic sensor, comprising laminated film(s) of magnetostrictive film(s) composed of an Fe alloy containing Ga and magnetostrictive film(s) composed of an Fe alloy containing Co, the laminated film(s) being deposited on at least one surface of a piezoelectric substrate.

8. The piezoelectric/magnetostrictive composite magnetic sensor according to claim 1, wherein magnetostrictive films are deposited on both surfaces of the piezoelectric substrate.

9. The piezoelectric/magnetostrictive composite magnetic sensor according to claim 2, wherein magnetostrictive films are deposited on both surfaces of the piezoelectric substrate.

10. The piezoelectric/magnetostrictive composite magnetic sensor according to claim 3, wherein magnetostrictive films are deposited on both surfaces of the piezoelectric substrate.

11. The piezoelectric/magnetostrictive composite magnetic sensor according to claim 4, wherein magnetostrictive films are deposited on both surfaces of the piezoelectric substrate.

12. The piezoelectric/magnetostrictive composite magnetic sensor according to claim 5, wherein magnetostrictive films are deposited on both surfaces of the piezoelectric substrate.

13. The piezoelectric/magnetostrictive composite magnetic sensor according to claim 6, wherein magnetostrictive films are deposited on both surfaces of the piezoelectric substrate.

14. The piezoelectric/magnetostrictive composite magnetic sensor according to claim 7, wherein magnetostrictive films are deposited on both surfaces of the piezoelectric substrate.
